(19) United States
(12) Patent Application Publication
(10) Pub. No.: US 2006/0227605 A1
(43) Pub. Date: Oct. 12, 2006

(54) Memory architectures including non-volatile memory devices

(76) Inventors: David S. Choi, Cupertino, CA (US); John D. Villasenor, San Francisco, CA (US)

Correspondence Address: CHRISTIE, PARKER & HALE, LLP, PO BOX 7068, PASADENA, CA, 91109-7068, US

(21) Appl. No.: 11/325,224

(22) Filed: Jan. 3, 2006

Related U.S. Application Data
(60) Provisional application No. 60/641,278, filed on Jan. 5, 2005.
(60) Provisional application No. 60/641,374, filed on Jan. 5, 2005.

(51) Int. Cl. G11C 14/00

(52) U.S. Cl. 365/185.08

(57) ABSTRACT

Architectures are described that can include integrated non-volatile memory modules. Integrated non-volatile memory modules are a form of memory that is integrated on a single chip and includes at least one volatile memory cell and at least one non-volatile memory device. Information can be loaded between the at least one memory cell and the at least one non-volatile memory device in coordination with the supply of power to the integrated non-volatile memory device. In many embodiments, the supply of power to the integrated non-volatile memory device and the loading of information between the volatile memory cells and non-volatile memory devices are controlled to conserve energy. One embodiment of the present invention includes processing circuitry connected to an integrated non-volatile memory module and a power supply connected to the processing circuitry and integrated non-volatile memory module. In addition, the integrated non-volatile memory module is integrated on a single chip and includes at least one volatile memory cell that is connected to at least one non-volatile memory device.

### CROSS-REFERENCE TO RELATED APPLICATION(S)

The present application claims the benefit of U.S. Provisional Application No. 60/641,278, filed Jan. 5, 2005, entitled “IMPROVED MEMORY ARCHITECTURE THROUGH NOVEL INTEGRATION OF NON-VOLATILE MEMORY”, and U.S. Provisional Patent Application No. 60/641,374, filed Jan. 5, 2005, entitled “IMPROVED ARCHITECTURE FOR POWER SAVINGS”, the contents of which are expressly incorporated herein by reference in their entirety.

### BACKGROUND

The present invention relates generally to memory architectures and more specifically to memory architectures that use memory devices that integrate both volatile and non-volatile memory circuits.

Memory can be used to store digital data. A number of different types of memory are available and the choice of memory used for a particular application can be informed by a number of factors including cost, complexity, size, memory refresh requirements, the ability of the memory to retain data in the absence of power, data read and/or write access times, power consumption and the amount of heat generated by the memory component. The ability of a memory to retain data in the absence of power is often referred to as the non-volatility of the memory.

The ability to retain data in the absence of power can be important to the operation of many electronic devices. Various types of non-volatile memory exist. Read-only memory (ROM) is a form of non-volatile memory that can be written to once and cannot subsequently be modified. Electrically-Erasable Programmable Read-Only Memory (EEPROM) is a form of non-volatile memory that can be modified. Flash memory refers to a category of EEPROM that provides fast read access times and the ability to perform multiple memory reads simultaneously while a single memory write is being performed at another memory location. Flash memory is usually implemented using an n-channel Metal Oxide Semiconductor (NMOS) transistor in a configuration referred to as a Floating-Gate Avalanche-Injection Metal Oxide Semiconductor (FAMOS) transistor. Despite the fact that Flash memory can be read or programmed a byte or a word at a time in a random access fashion, Flash memory typically requires memory to be erased a block at a time. A common Flash memory block size is 256 kBytes. Therefore, Flash memory does not offer random-access rewrite or erase operations.

The inability for typical Flash memory to provide random-access rewrite or erase operations can be compensated for using file systems that spread writes over the media and accommodate the comparatively lengthy time required to erase a Flash memory block. A Flash memory file system typically updates a Flash memory entry by writing a new copy of the changed data to a fresh block of Flash memory and then remaps file pointers to the freshly written block. Once the data has been written to the fresh block, the old block can be erased. A file system known as the File Allocation Table (FAT) developed by Microsoft Corporation of Redmond, Wash. is an example of a file system that can be used with Flash memory.

In addition to the NMOS logic used in the construction of Flash memory, other types of processes can be used to create memory. A number of different types of random access memory can be implemented using a Complementary Metal-Oxide Semiconductor (CMOS) based process. Conventional Dynamic Random Access Memory (DRAM) and Static Random Access Memory (SRAM) are both examples of memory that can be implemented in a CMOS based process. The voltage and current (and therefore power) used when erasing information stored in the CMOS circuits of DRAM or SRAM are significantly lower than the voltage and current required to erase data stored in the NMOS circuits of a Flash memory. However, conventional DRAM and SRAM are incapable of retaining data once power supply is removed. DRAM differs from SRAM in that preserving data in DRAM requires that the data be continuously rewritten to the DRAM, whereas SRAM retains its contents as long as power remains applied. The process of rewriting data to a DRAM is often referred to as refreshing the data.

Many memory architectures include various different types of volatile and non-volatile memory devices to balance the competing design factors mentioned above. Each of the different memory components can require a different power supply and necessitate the use of different communication hardware and/or protocols for data exchange.

U.S. Pat. No. 6,798,008 to Choi entitled “Non-volatile Dynamic Random Access Memory” and U.S. Pat. No. 6,965,524 to Choi entitled “Non-volatile Static Random Access Memory” describe circuits that are capable of being implemented in CMOS, which combine a non-volatile device and either a DRAM or SRAM cell. Data stored in the DRAM or SRAM cell can also be loaded into the non-volatile device. Further information concerning the creation of non-volatile devices in CMOS and memory arrays including non-volatile CMOS devices can be found in U.S. Pat. No. 6,806,148 to Choi et al. entitled “Method of manufacturing non-volatile memory device”, U.S. Pat. No. 6,954,377 to Choi et al. entitled “Non-volatile differential dynamic random access memory”, U.S. Pat. No. 6,695,145 to Choi entitiled “Non-volatile memory device”, U.S. Patent Publication 2005/0161718 to Choi entitled “Non-volatile DRAM and a method of making thereof”, U.S. Patent Publication 2005/0170586 to Choi entitled “Method of manufacturing non-volatile DRAM” and U.S. Patent Publication 2005/0219913 to Choi et al. entitled “Non-volatile Memory Array”. The disclosures of U.S. Pat. Nos. 6,798,008, 6,806,148, 6,954,377, 6,695,145 and 6,965,524 and U.S. Patent Publications 2005/0161718, 2005/0170586 and 2005/0219913 are incorporated by reference herein in their entirety.

### SUMMARY OF THE INVENTION

Embodiments of the present invention can include integrated non-volatile memory modules that are integrated on a single chip and include at least one volatile memory cell and at least one non-volatile memory device. In another aspect of the invention, information is loaded between the at least one memory cell and the at least one non-volatile memory device in coordination with the supply of power to the integrated non-volatile memory device. In many embodiments, the supply of power to the integrated non-volatile memory device is controlled to conserve energy.

One embodiment of the present invention includes processing circuitry connected to an integrated non-volatile memory module and a power supply connected to the processing circuitry and integrated non-volatile memory module. In addition, the integrated non-volatile memory module is integrated on a single chip and includes at least one volatile memory cell that is connected to at least one non-volatile memory device.

In a further embodiment, the integrated non-volatile memory module includes at least one control input that is configured to load data stored in a volatile memory cell into a non-volatile memory device.

In another embodiment, the processor is configured to provide a signal to the at least one control input of the integrated non-volatile memory module that causes data to be loaded from a volatile memory cell in the integrated non-volatile memory into a non-volatile memory device in the integrated non-volatile memory and the processor is configured to provide a signal to the power supply that causes the power supply to remove power to the volatile memory cell and the non-volatile memory device in the integrated non-volatile memory module.

In a still further embodiment, the power supply is configured to provide a signal to the at least one control input of the integrated non-volatile memory module that causes data to be loaded from a volatile memory cell in the integrated non-volatile memory module into a non-volatile memory device in the integrated non-volatile memory module and the power supply is configured to remove power to the volatile memory cell and the non-volatile memory device in the integrated non-volatile memory module.

In still another embodiment, the power supply receives power from an external power source and the power supply is configured to sense an actual or impending interruption to the supply of power from the external power source.

In a yet further embodiment, the power supply includes a battery as a power source in addition to the external power source.

In yet another embodiment, the integrated non-volatile memory module includes at least one control input that is configured to load data stored in a non-volatile memory device into a volatile memory cell.

In a further embodiment again, the processor is configured to provide a signal to the power supply that causes the power supply to provide power to a volatile memory cell and a non-volatile memory device in the integrated non-volatile memory module and the processor is configured to provide a signal to the at least one control input of the integrated non-volatile memory module that causes data to be loaded from the non-volatile memory device into the volatile memory cell.

In another embodiment again, the power supply is configured to controllably supply power to a volatile memory cell and a non-volatile memory device in the integrated non-volatile memory module and the power supply is configured to provide a signal to the at least one control input of the integrated non-volatile memory module that causes data to be loaded from the non-volatile memory device into the volatile memory cell.

In a further additional embodiment, the processing circuitry and integrated non-volatile memory module are connected via a bus system.

Another additional embodiment also include a hard disk drive connected to the processing circuitry and the integrated non-volatile memory module via the bus system.

In a still further embodiment again, the processing circuitry includes a central processing unit.

Still another embodiment again also includes non-volatile memory connected to the processing circuitry and the integrated NVM module via the bus system.

In a still yet further embodiment, the processing circuitry includes a video game processor.

In still yet another embodiment, the processing circuitry includes an embedded processor.

In a still further additional embodiment, the processing circuitry and the integrated non-volatile memory module are integrated on the same chip.

In still another additional embodiment, the processing circuitry includes an adaptive equalizer connected to the integrated non-volatile memory module and wherein the tap coefficients of the adaptive equalizer are stored in the integrated non-volatile memory module.

In a yet further embodiment again, the processing circuitry includes an authentication circuit connected to the integrated non-volatile memory module and an encryption key is stored in the integrated non-volatile memory module.

In yet another embodiment again, the processing circuitry includes a psuedorandom noise generator connected to the integrated non-volatile memory module and wherein a psuedorandom noise authentication state and key are stored in the integrated non-volatile memory module.

In a yet further additional embodiment, the processing circuitry includes multiple processing circuits and the single integrated device includes multiple integrated non-volatile memory modules that are connected to different processing circuits.

In a yet further additional embodiment, the processing circuitry includes a convolutional encoder connected to a plurality of integrated non-volatile memory modules and the state of the convolution encoder is stored in the integrated non-volatile memory modules.

In another further embodiment, the processing circuitry includes multiple processing circuits distributed across multiple integrated devices and a plurality of those integrated devices also include at least one integrated non-volatile memory module.

In still another further embodiment, one of the devices includes a digital signal processor and an integrated non-volatile memory module, a second device includes a central processor unit and an integrated memory module and both of the devices are connected to the power supply.

Yet another further embodiment also includes a second integrated non-volatile memory module connected to the power supply. In addition, the processing circuitry includes a digital signal processor integrated on a first device and a central processing unit integrated on a second device and the digital signal processor, the central processing unit, the first integrated non-volatile memory module and the second integrated non-volatile memory module are connected via a bus system.

An embodiment of the method of the invention includes determining whether a portion of the integrated non-volatile memory module that includes the volatile memory cell and the integrated non-volatile device is likely to be required within a predetermined time period, loading information in the volatile memory cell into the non-volatile device and removing power from the volatile memory cell and the non-volatile device.

A further embodiment of the method of the invention also includes waiting for the portion of the integrated non-volatile memory to be required, waking up the portion of the integrated non-volatile memory and loading data from the non-volatile memory device into the volatile memory cell.

In another embodiment of the method of the invention, determining whether a portion of the integrated non-volatile memory that includes the volatile memory cell and the integrated non-volatile device is likely to be required further comprises receiving a user instruction indicative of the portion of integrated non-volatile memory not being required.

In a still further embodiment of the method of the invention, determining whether a portion of the integrated non-volatile memory that includes the volatile memory cell and the integrated non-volatile device is likely to be required further comprises receiving an automatically generated instruction indicative of the portion of integrated non-volatile memory not being required.

In still another embodiment of the method of the invention an instruction is automatically generated when the portion of the integrated non-volatile memory has not been required for a second predetermined period of time.

In a yet further embodiment of the method of the invention, the duration of the second predetermined period of time is determined by performing analysis of the frequency with which the portion of integrated non-volatile memory is required.

In yet another embodiment of the method of the invention the portion of integrated non-volatile memory is an entire integrated non-volatile memory module.

### BRIEF DESCRIPTION OF THE DRAWINGS

FIG. 1 is a schematic diagram of an embodiment of an architecture in accordance with the present invention;

FIG. 2 is a is a schematic diagram of an embodiment of an architecture in accordance with the present invention that includes a bus system;

FIG. 3 is a flow chart showing an embodiment of a process in accordance with the present invention for loading information between volatile memory cells and non-volatile devices in an integrated non-volatile memory module;

FIG. 4 is a flow chart showing an embodiment of a process in accordance with the present invention for determining whether an integrated memory module is unlikely to be accessed for a time greater than a predetermined period of time;

FIG. 5 is a flow chart showing an embodiment of a process in accordance with the present invention that can be used to statistically analyze the use of an integrated non-volatile memory device;

FIG. 6 is a schematic circuit diagram of an embodiment of an architecture in accordance with the present invention that includes a hard disk drive;

FIG. 7 is a schematic circuit diagram of an embodiment of an architecture in accordance with the present invention that can be configured for use in a video game system;

FIG. 8 is a schematic circuit diagram of an embodiment of an architecture in accordance with the present invention that can be configured for use in an embedded system;

FIG. 9 is a schematic circuit diagram of an embodiment of a processor in accordance with the present invention that includes multiple integrated non-volatile memory modules;

FIG. 10 is a flow chat showing an embodiment of a process in accordance with the present invention for loading information in a look up table between volatile memory cells and non-volatile memory devices in an integrated non-volatile memory module;

FIG. 10a is a flow chart showing an embodiment of a process in accordance with the present invention for loading a frame of video information from volatile memory cells to non-volatile memory devices in an integrated non-volatile memory module;

FIG. 11 is schematic circuit diagram of an embodiment of a convolutional encoder circuit in accordance with the present invention that includes integrated non-volatile memory modules;

FIG. 12 is a flow chart showing an embodiment of a process in accordance with the present invention for loading information indicative of the state of a convolutional encoder between volatile memory cells and non-volatile memory devices in an integrated non-volatile memory module;

FIG. 13 is a schematic circuit diagram of another embodiment of a convolutional encoder circuit in accordance with the present invention that includes integrated non-volatile memory modules;

FIG. 14 is a schematic circuit diagram of an embodiment of an adaptive equalizer in accordance with the present invention that includes an integrated non-volatile memory module;

FIG. 15 is a flow chart showing an embodiment of a process in accordance with the present invention for loading the coefficients of an adaptive equalizer between volatile memory cells and non-volatile memory devices in an integrated non-volatile memory module;

FIG. 16 is a schematic circuit diagram of an embodiment of an authentication system in accordance with the present invention that includes an integrated non-volatile memory module;

FIG. 17 is a flow chart showing an embodiment of a process in accordance with the present invention for loading an encryption key between volatile memory cells and non-volatile memory devices in an integrated non-volatile memory module;

FIG. 18 is a schematic circuit diagram of an embodiment of a psuedorandom noise generator in accordance with the present invention that includes an integrated non-volatile memory module;

FIG. 19 is a schematic circuit diagram of an embodiment of an adaptive filtering arithmetic coding system in accordance with the present invention that includes an integrated two non-volatile memory modules;

FIGS. 20a and 20bare flow charts showing embodiments of processes in accordance with the present invention for loading information used by an adaptive filtering arithmetic coding system between volatile memory cells and non-volatile memory devices in integrated non-volatile memory modules; and

FIG. 21 is a schematic circuit diagram of another embodiment of an adaptive filtering arithmetic coding system in accordance with the present invention that includes a digital signal processor, a central processing unit, a first integrated non-volatile memory device and a second integrated non-volatile memory device that are connected via a bus system.

### DETAILED DESCRIPTION OF THE INVENTION

Turning now to the drawings, architectures that include at least one integrated non-volatile memory (NVM) module are shown. Integrated NVM modules are circuits integrated onto a single chip or device that include at least one volatile memory cell connected to at least one non-volatile memory device. The architectures typically include processing circuitry that stores data in the integrated NVM module and power supply circuitry that provides power to the processing circuitry and integrated NVM module. Embodiments of architectures in accordance with the present invention can be configured to coordinate data storage in the integrated NVM module with the supply of power to the integrated NVM module. Many embodiments include the processing circuitry and integrated NVM module integrated on a single chip or device. Embodiments of architectures in accordance with the present invention can also be configured to store system critical data in the integrated NVM in the event of a power failure. In a number of embodiments, the architecture coordinates the transfer of data between volatile memory cells and non-volatile memory devices using hardware flags/bits and/or software data structures to identify data that is desired to be saved in the event of an interruption to the supply of power. Many embodiments of processor in accordance with the present invention include determining when information in an integrated NVM module is not required and loading the information into the non-volatile memory device and powering down the integrated NVM module until the information is required. At which point, the integrated NVM module can be powered up and the information loaded back into the volatile memory cells on the integrated NVM module.

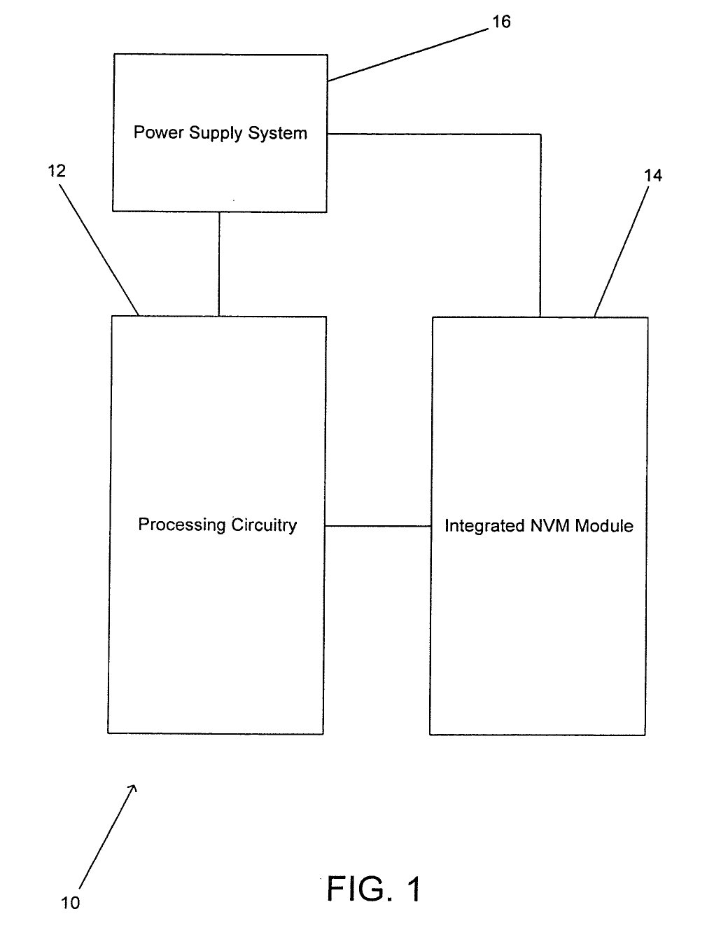

A schematic of an architecture in accordance with the present invention is shown in FIG. 1. The architecture 10 includes processing circuitry 12 connected to an integrated NVM module 14. Both the processing circuitry 12 and the integrated NVM module 14 are connected to a power supply system 16. Although in the illustrated embodiment the processing circuitry 12 and the integrated NVM module 14 are illustrated separately, many embodiments of architectures in accordance with the present invention integrate processing circuitry and the circuitry of the integrated NVM module on a single chip or device. Several embodiments of the present invention where processing circuitry and the circuitry of the integrated NVM module are integrated onto a single chip are discussed below.

In various embodiments, the processing circuitry 12 can be a microprocessor, a digital logic circuit or a combination of a microprocessor and digital logic circuits. The processing circuitry 12 is configured to read and write data to/from the integrated NVM module 14. In many embodiments, the processing circuitry 12 communicates with the integrated NVM module 14 via bus hardware. In other embodiments, the processing circuitry 12 is directly connected to memory cells within the integrated NVM module 14.

In many embodiments, the integrated NVM module 14 includes a circuit integrated onto a single chip including at least one volatile memory cell and at least one non-volatile memory device, where at least one of the volatile memory cells is connected to a non-volatile memory device and data can be directly transferred between the volatile memory cell and the non-volatile memory device. As indicated above, other circuitry such as processing circuitry can be integrated onto the same chip as the integrated NVM module and more than one integrated NVM module can be integrated on the same chip. In a number of embodiments, a plurality of volatile memory cells are connected to a single non-volatile device and a group of embodiments include a volatile memory cell that is connected to a plurality of non-volatile memory devices. In several embodiments, the volatile memory cell and non-volatile device are implemented using a CMOS based process. In many embodiments, the processing circuitry 12 can randomly write and read to/from the volatile memory cells. In a number of embodiments, the memory cells are all SRAM, all DRAM or a combination of SRAM and DRAM. The integrated NVM module 14 can include control inputs that control the transfer of data between the volatile memory cells and the non-volatile devices. In several embodiments, the control inputs can cause all of the data stored in the volatile memory cells to be simultaneously loaded into the non-volatile devices and vice versa. In one embodiment, the processing circuitry 12 is configured to provide inputs to the control inputs of the integrated NVM module 14. In other embodiments the power supply system 16 is configured to provide inputs to the control inputs of the integrated NVM module 14.

The power supply system 16 is circuitry that is configured to provide supply voltages to the processing circuitry 12 and the integrated NVM module 14. In several embodiments, the power supply system 16 also includes power management circuitry (not shown) that can selectively supply power to the processing circuitry 12 and the integrated NVM module 14 to limit the power consumed by the architecture. In many embodiments, the power supply circuitry 16 includes outputs that are connected to control inputs of the integrated NVM module 14. The power supply circuitry 16 can provide signals on its outputs that cause data stored in volatile memory cells within the integrated NVM module 14 to be loaded into non-volatile devices prior to the power supply circuitry 16 removing supply power to the integrated NVM module 14. In other embodiments, the loading of data from volatile memory cells to non-volatile devices within the integrated NVM module 14 and the removal of supply power to the integrated NVM module 14 are coordinated by the processing circuitry 12 via control inputs that are supplied to the integrated NVM module 14 and the power supply circuitry 16. In several embodiments where the processor coordinates data loading and power supply removal, the power supply circuitry does not provide any control inputs to the integrated NVM module 14 relating to data loading or power supply removal. In many other embodiments, the power supply circuitry provides control inputs to load data from the volatile memory cells into the non-volatile devices in response to the detection of a an interruption in power supply such as a power failure or the amount of charge stored in an internal battery falling below a predetermined threshold. In several embodiments, the power supply system 16 can include one or more batteries. In many embodiments, the power supply system includes a battery that is configured to provide power to load data from volatile memory cells to non-volatile devices in the event of an actual or impending interruption in supply from external sources. An external source is typically a source that is external to the power supply circuitry such as main power or battery.

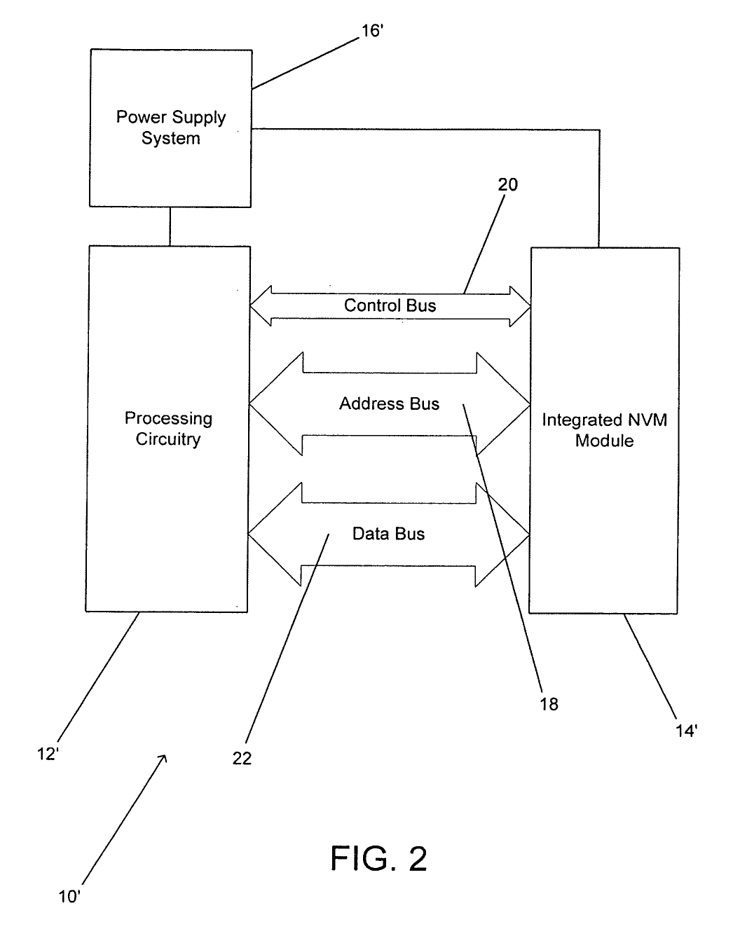

As discussed above, processing circuitry 12 in accordance with an embodiment of the present invention can provide control inputs to the integrated NVM module to cause information to be stored in one or more of the non-volatile devices. An embodiment of an architecture in accordance with the present invention where the processing circuitry can read and write data to/from an integrated NVM module using address, control and data busses is shown in FIG. 2. The architecture 10′ includes processing circuitry 12′ connected to the integrated NVM module 14′ via an address bus 18, a control bus 20 and a data bus 22. The processing circuitry 12′ and the integrated NVM module 14′ are powered via connections to the power supply system 16′.

The address 18, control 20 and data 22 busses perform functions similar to those typically attributed to such buses. In several embodiments, the processing circuitry can control whether data provided via the data bus should be stored in volatile memory cells or in non-volatile devices using signals provided via the control bus. In other embodiments, volatile memory cells and non-volatile devices are separately addressable by the processing circuitry.

In several embodiments of architectures in accordance with the present invention, the processing circuitry includes a microprocessor that is configured via software. In many embodiments, the software can identify particular pieces of information as being desirable to retain in the event of a power failure. In a number of embodiments, a data structure is maintained in software that indicates the information stored in volatile memory cells that should be moved to a non-volatile device in the event of a power failure. In this way, processing circuitry can respond to a power interruption sensed by a power supply system by loading data from designated volatile memory cells into the non-volatile devices connected to those memory cells. Selective loading of information can occur more rapidly and result in the use of less power than loading the entire contents of the memory into the non-volatile devices. In other embodiments, the integrated NVM module can include an additional bit or flag associated with each volatile memory cell that indicates whether the information should be loaded into a non-volatile device in the event of a power failure.

As discussed above, the power supply system 16 can selectively supply voltage to various components within the architecture 10. Conserving power to preserve battery life is important in mobile applications. Many architectures in accordance with the present invention seek to conserve power by powering down portions of the architecture that are not required. In one embodiment, power from the power supply system 16 is removed from a portion of an integrated NVM module. Prior to powering down a portion of an integrated NVM module, data that is desired to be available upon resumption of power can be loaded from volatile memory cells into non-volatile devices. The process of loading data from volatile memory cells into non-volatile devices consumes power. An embodiment of a power management process in accordance with the present invention involves powering down a portion of an integrated NVM module provided that the power consumed in powering down the integrated NVM module is less than the power that would have been consumed had that portion of the integrated NVM module remained powered during the period of inactivity.

In many embodiments, the architecture shown in FIG. 2 can be utilized in a music player. The music player can store music in the form of individual songs in the integrated NVM module. In order to conserve power, the power supply system and the processing circuitry can use play lists and other information about the sequence in which a user intends to play songs stored in the integrated NVM module to power down blocks of memory in the integrated NVM module that contain songs that are not likely to be played. In many embodiments, the songs stored in the integrated NVM module include information concerning the duration of the time and the processing circuitry can include information concerning the time remaining. The time remaining information can be used in conjunction with a play list generated by the music player's user interface to determine the next song that is likely to be played and the time at which the blocks of memory in the integrated NVM module that contain the data corresponding to that song should be powered up.

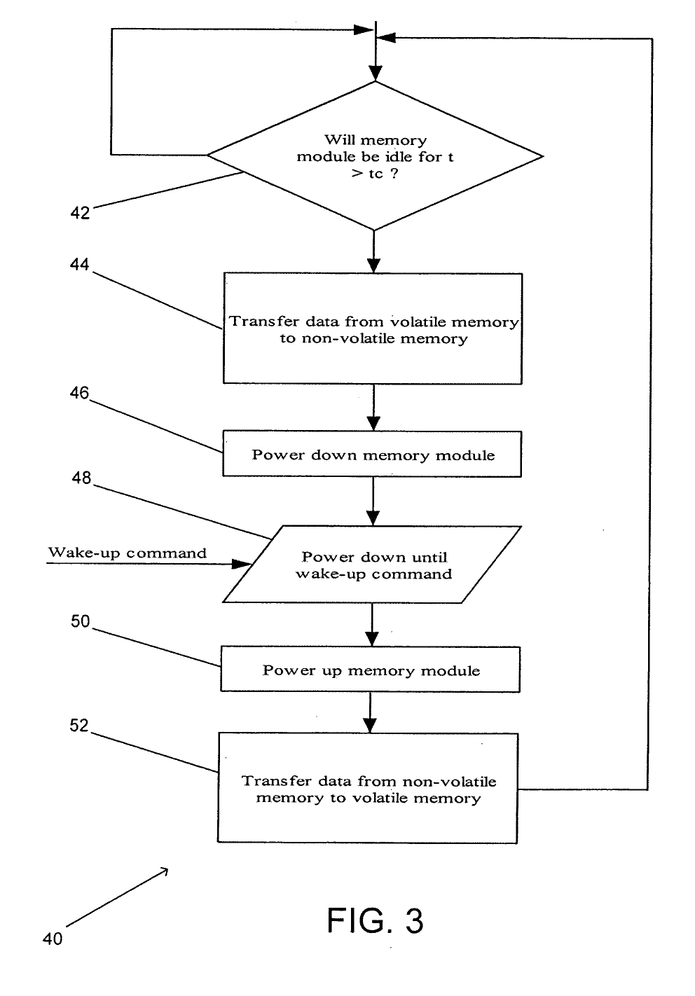

A process for powering down a portion of an integrated NVM module in accordance with an embodiment of the present invention is shown in FIG. 3. The process 40 includes determining (42) whether the integrated NVM module (or a portion of an integrated NVM module) is likely to be idle for a period of time t greater than a predetermined period of time tc. If the integrated NVM module is not likely to be idle for a period of time greater than tc, then the integrated NVM module is not powered down.

When a determination is made that the integrated NVM module is likely to be idle for a period of time greater than tc, then data can be transferred (44) from volatile memory cells to non-volatile memory devices. Following the transfer, the integrated NVM module (or a portion of the integrated NVM module) can be powered down (46).

The integrated NVM module remains (48) powered down until a wake-up command is received. When a wake-up command is received, the integrated NVM module is powered up (50) and data from the non-volatile devices is loaded (52) into volatile memory cells. The activity of the integrated NVM module is then monitored for an opportunity to power down the integrated NVM module to conserve power.

In several embodiments, the determination that an integrated NVM module (or portion of an integrated NVM module) is likely to be idle for a time t greater than tc can be made by the user or by automated analysis of algorithms performed by processing circuitry connected to the integrated module. In many embodiments, a user can elect to suspend the activity of the architecture until the user provides a wake up instruction. In other embodiments, an automatic algorithm can be used to determine whether an integrated NVM module (or portion of an integrated NVM module) can be powered down to conserve power. In many embodiments, an automatic algorithm is developed based upon the memory usage patterns of a particular architecture when performing a particular activity.

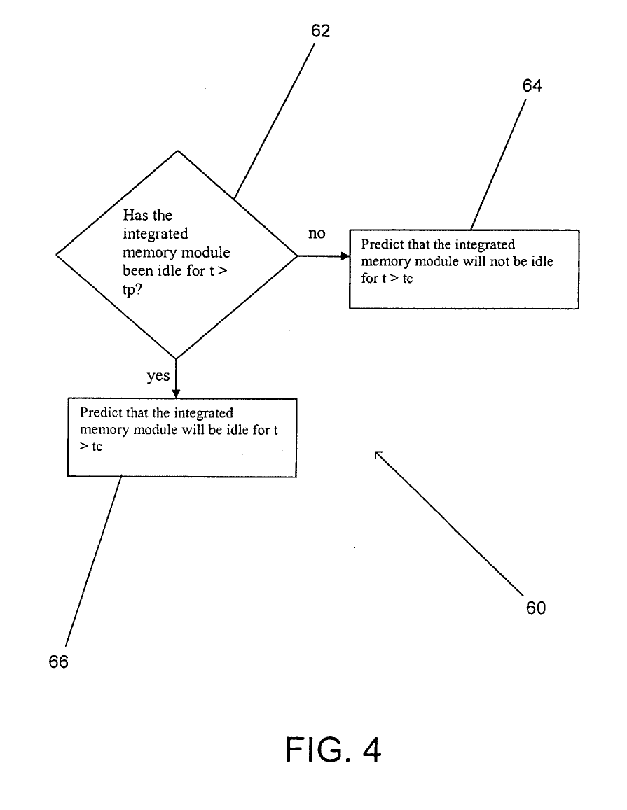

Many different automatic processes can be used for determining whether an integrated NVM module is likely to remain idle for a period of time of sufficient duration that powering down the integrated NVM module would conserve power (i.e. a period of time greater than tc). An embodiment of an automatic process in accordance with the present invention for determining whether all or a portion of an integrated NVM module is likely to remain idle for a time t greater than tc is shown in FIG. 4. The process 60 assumes that if the integrated NVM module has remained idle for a period tp then the integrated NVM module is likely to remain idle for a period of time greater than tc. The process includes determining (62) whether the integrated NVM module (or portion of the integrated NVM module) has remained idle for a time t greater than tp. If the memory module has not been idle for a time period greater than tp, then the process predicts (64) that the integrated NVM module (or portion of the integrated NVM module) is not likely to be idle for a period of time t that is greater than tc. If the memory module has been idle for a time period greater than tp, then the process predicts (66) that the integrated NVM module (or portion of the integrated NVM module) is likely to remain idle for a period of time t that is greater than tc.

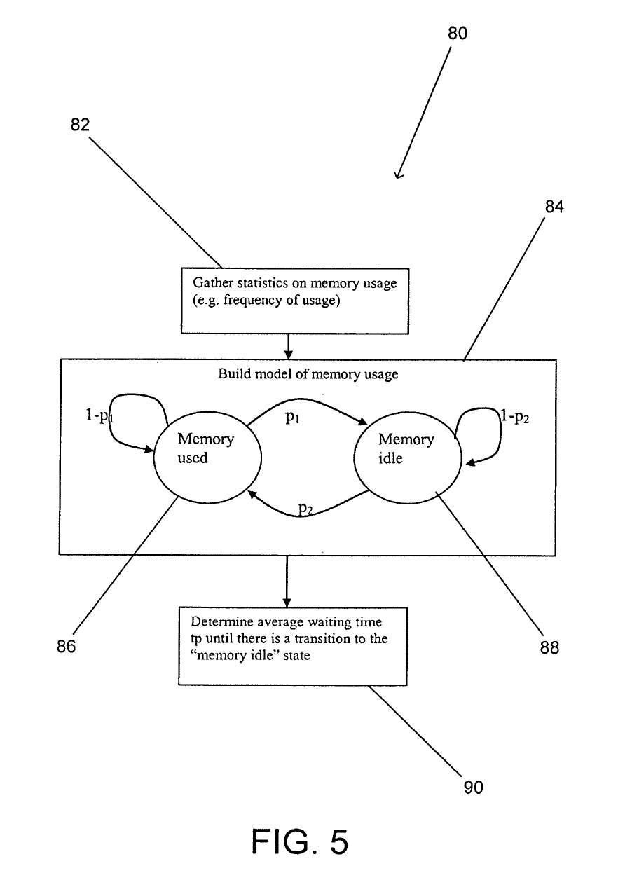

Many techniques exist for determining the value of tp in FIG. 4. An embodiment of a process in accordance with the present invention that can be used to determine the value tp by observing the operation of the architecture on which the algorithm shown in FIG. 4 is to be performed is shown in FIG. 5. The process 80 includes gathering (82) statistics about the utilization of the integrated NVM module (or portion of the integrated NVM module). Once the statistics are gathered, a model can be constructed. In the illustrated embodiment, a first order Markov model is used, however, other models can be used including models that can account for patterns that occur over significant period of time. An example of a model in accordance with the present invention is illustrated in FIG. 5. The model 84 includes a first state 86 and a second state 88. The first state is indicative of the integrated NVM module (or portion of the integrated NVM module) being utilized. The second state is indicative of the integrated NVM module (or portion of the integrated NVM module) remaining idle. Based upon the usage statistics, the probability pi that a transition will occur from the first state to the second state and the probability P2 that a transition will occur form the second state to the first state can be determined. Once the probabilities pi and P2 have been determined, the average waiting time required for a transition from the first state to the second state to occur can be assigned (90) as the value of tp. In many embodiments of the process shown in FIG. 5, the memory used state is defined as any time in which a memory read or write operation is being performed and the memory idle state is defined as any time in which a memory read or write is not being performed. In embodiments, where the processing circuitry accessing the integrated NVM module includes branch prediction, the memory used state can be defined as any time in which a memory read or write is not being performed and a memory read or write is not predicted. Similarly, the memory idle state can be defined as any time at which a memory read or write is not being performed or predicted. In a number of further embodiments, the memory idle state can be defined in the memory not having been accused for a predetermined period of time.

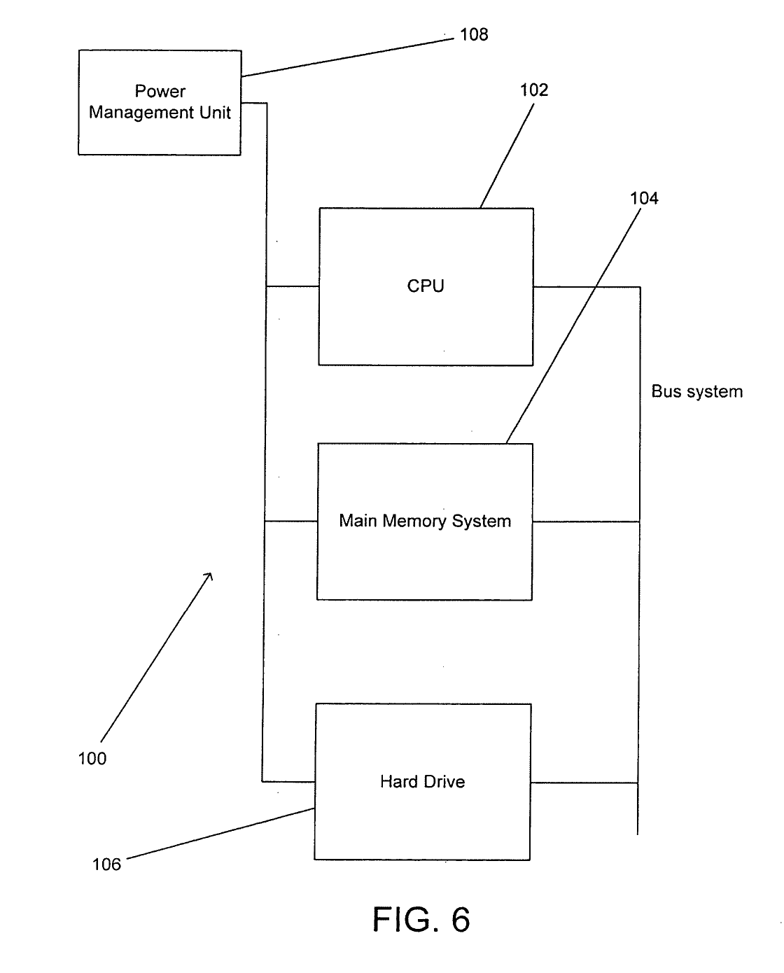

Turning now to FIG. 6, an embodiment of a computer system in accordance with the present invention is illustrated. The computer system 100 includes a central processing unit (CPU) 102 that is connected via a bus system to a memory system 104, which can include an integrated NVM module, and a hard disk drive 106. The CPU 102, memory system 104 and hard disk drive 106 are all connected to a power management unit 108.

In several embodiments, the CPU 102 includes one or more integrated NVM modules. In addition, the memory system 104 can include one or more integrated NVM modules and/or memory that does not take the form of an integrated NVM module.

In many embodiments, the architecture shown in FIG. 6 can be used in the construction of a computer in accordance with the present invention. The operating system and potentially additional programs that are loaded during the start up of the computer can be contained within one or more integrated NVM modules either within the main memory system or within the CPU. Upon boot up of the computer, the operating system and any other desired programs can be simultaneously loaded into the volatile memory cells of the integrated NVM module(s).

In the embodiment illustrated in FIG. 6, the power management unit is configured to conserve power by selectively activating the CPU 102, memory system 104 and hard disk drive 106 in accordance with the processes described above. In many embodiments, the operation of the power management unit is impacted by the location of critical data and whether the CPU 102, memory system 104 and/or hard disk drive 106 include integrated NVM modules.

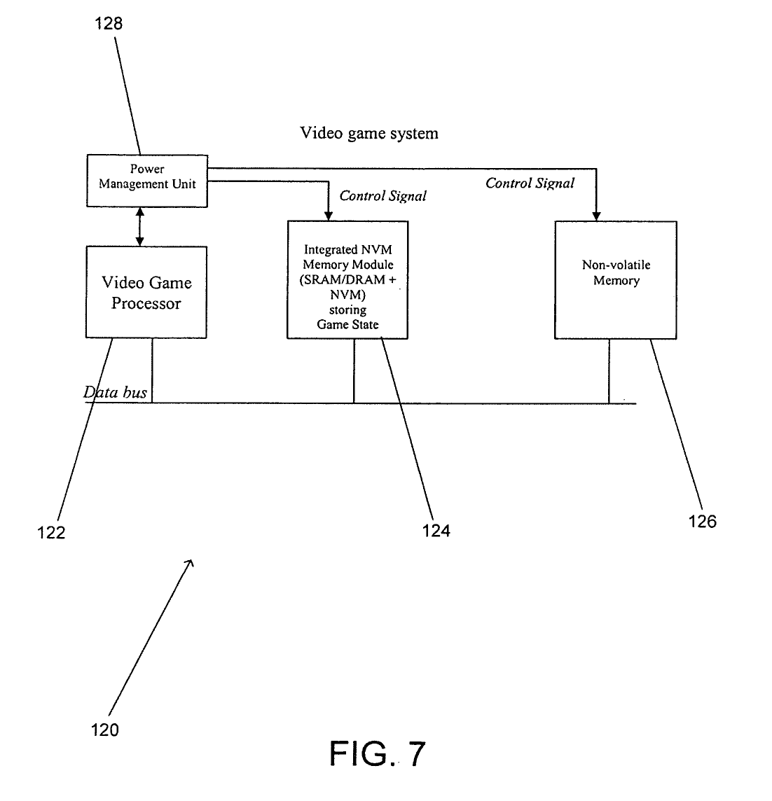

An embodiment of a video gaming system in accordance with the present invention is shown in FIG. 7. The system 120 includes a video game processor 122 that is connected to an integrated NVM module 124 and a non-volatile memory 126 via bus system. The video game processor 122, integrated NVM module 124 and the non-volatile memory 126 are all connected to a power management unit 128. In several embodiments, the video game processor and circuitry from an integrated NVM modules can be integrated into a single device.

In many embodiments, the non-volatile memory 126 can be a CD-ROM or Flash memory device or one or more non-volatile storage devices capable of storing information concerning the video game. In addition, the video game processor 122 is configured to retrieve information from the non-volatile memory 126 and store the information in the integrated NVM module 124. In a number of embodiments, a portion of the integrated NVM module 124 is reserved by the video game processor for storage of information relevant to a particular video game stored on the non-volatile memory. In these embodiments, information stored in the reserved portion of the integrated NVM module 124 can be stored in non-volatile devices during inoperation of the video game. The information stored in the non-volatile devices can be later retrieved and used to restore the particular video game to which the information relates to a particular game state. In several embodiments, the location of the reserved portion of the integrated NVM module 124 can be indicated using hardware flags or bits within the integrated NVM module or indicated in software (see discussion above).

As discussed above, the power management unit can control the supply of power to the video game processor 122, integrated NVM module 124 and/or non-volatile memory 126 in a way that conserves power.

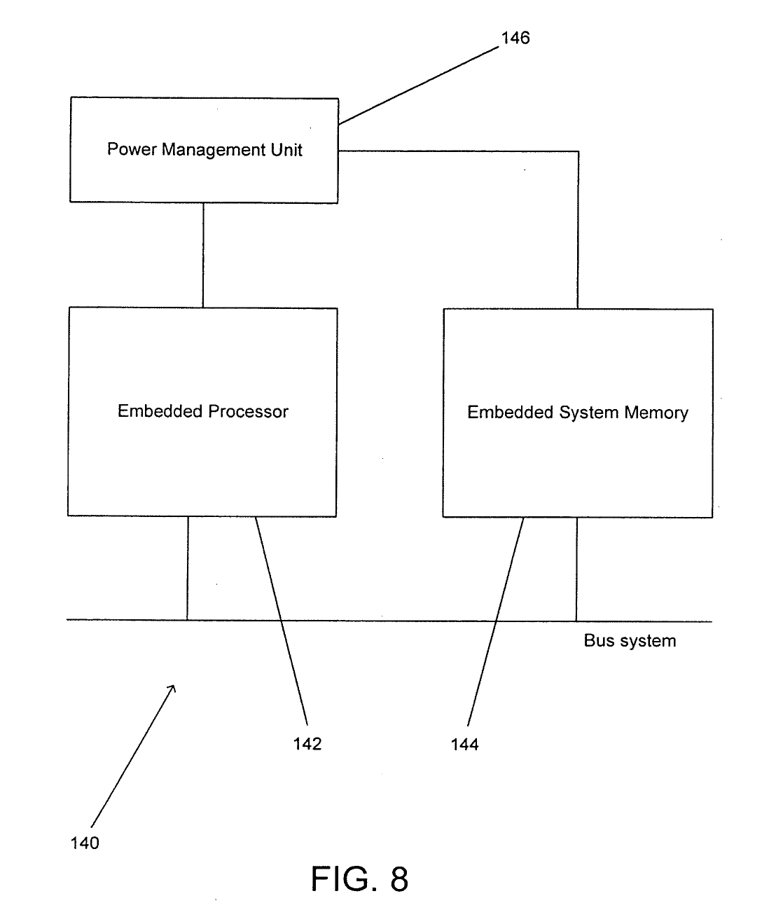

An embodiment of an embedded system in accordance with the present invention is shown in FIG. 8. The embedded system 140 includes an embedded processor 142 that is connected to an embedded system memory 144 via a bus system. The embedded processor 142 and the embedded system memory 144 are connected to a power management system 146.

In the illustrated embodiment, the embedded processor and the embedded system memory are shown as distinct components. In many embodiments, the embedded processor and the circuits of an integrated NVM module can be integrated onto a single device to provide the combination of the embedded processor and embedded memory system shown in FIG. 8. In many embodiments, the embedded system memory includes an integrated NVM module.

In many embodiments, the software of the embedded processor is stored in an integrated NVM module in the embedded system memory. In many instances, the stored software can be used to boot the embedded processor and provide the embedded processor with its operating software. When the embedded processor is inactive, the software can be stored in non-volatile devices within the integrated NVM module. In addition, the software of the embedded device can be readily updated by loading the new software into the embedded system memory and storing the new software in the integrated NVM module.

The integration of processing circuitry and the circuitry of an integrated NVM module onto a single chip or device has been discussed above. In many embodiments of the present invention, the circuitry of an integrated NVM module is integrated in multiple locations within a microprocessor. Providing multiple integrated NVM modules within a processing circuit can enable frequently used information to be cached on a processing chip in a manner that allows the memory storing the information to be powered down during periods of inactivity.

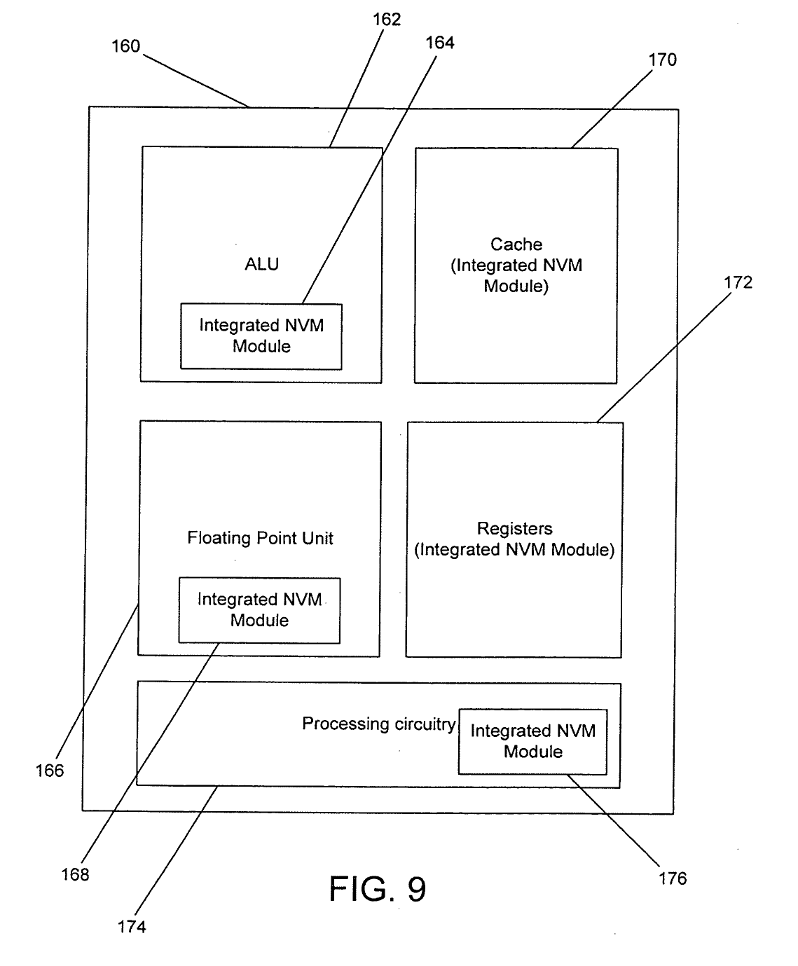

An embodiment of a processor in accordance with the present invention that includes multiple integrated NVM modules is shown in FIG. 9. The processor 160 includes a number of circuits that are integrated with circuitry of integrated NVM modules. The processor includes 160 an Arithmetic Logic Unit (ALU) 162 that includes an integrated NVM module 164, a memory cache 170 that can be implemented at least partially using an integrated NVM module, registers 172 that also can be impleted at least partially using an integrated NVM module, a Floating Point Unit 174 that includes an integrated NVM module 176 and additional circuitry 178 that also includes an integrated NVM module. The use of integrated NVM modules in the processor 160 shown in FIG. 9 enables the powering up and down of circuits within the processor to conserve energy when the circuits are not being utilized. In other embodiments of processors in accordance with the present invention, other combinations of processing circuitry can be included in the processor that are connected to one or more integrated NVM modules and the integrated NVM modules can be integrated in ocnjunction with conventional DRAM and/or SRAM memory.

As discussed above, frequently used information can be stored within an integrated NVM module that has been integrated into the circuitry of a processor. Storing the information in this manner enables the information to be loaded into non-volatile devices within the integrated NVM module during periods of inactivity and the circuitry associated with the integrated NVM module can be powered down.

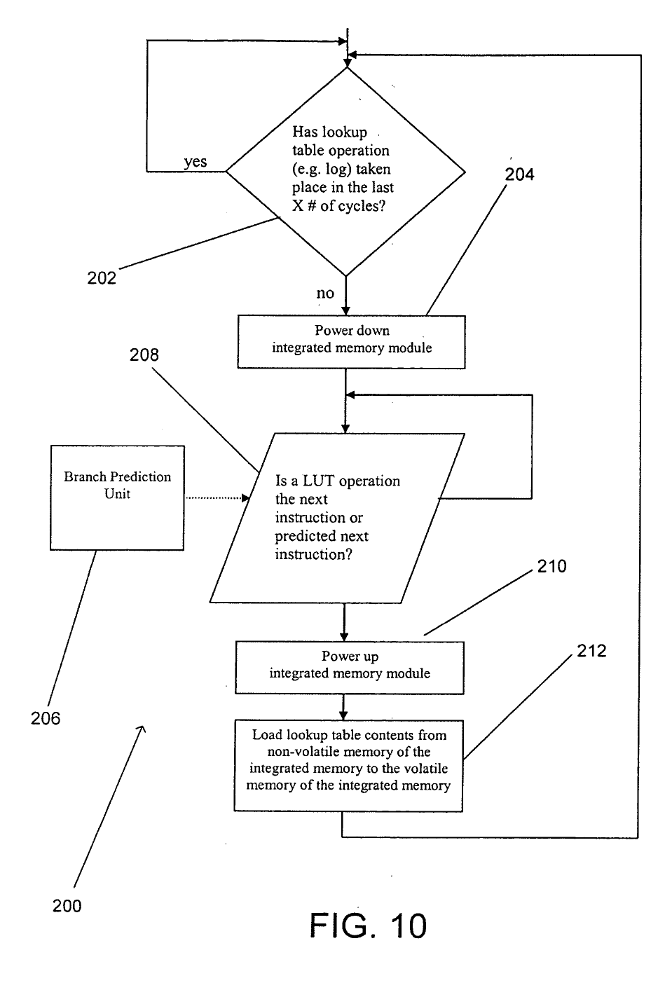

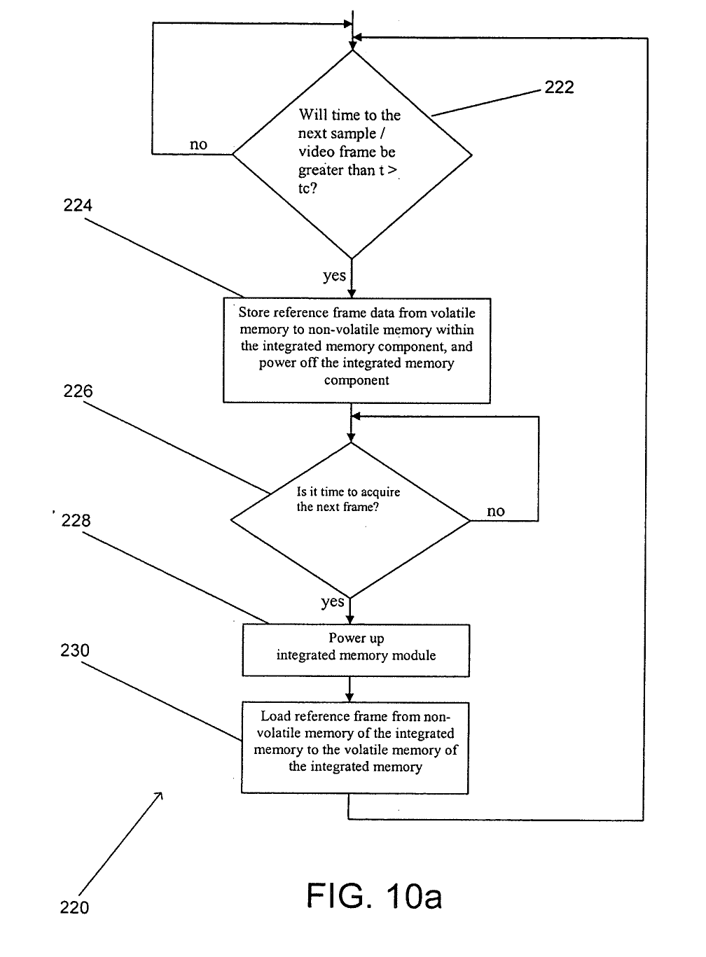

In many embodiments of the present invention integrated NVM modules are used to store look-up tables within a processor. A process for controlling the supply of power in accordance with the present invention to the circuitry of an integrated NVM module containing a look-up table is shown in FIG. 10. The process 200 includes determining (202) whether an operation involving the lookup table has taken place in the last X cycles. In many embodiments, the value of X can be ascertained in accordance with one of the statistical modeling processes described above for determining the value of tp. In the event that such an operation has not occurred during the last X number of cycles, then the lookup table can be loaded from the volatile memory cells within the integrated NVM module into the non-volatile memory devices within the integrated NVM module and the integrated NVM module can be powered down (204). In processors that include a branch prediction unit (206), the branch prediction unit can be monitored (208) to determine whether an operation that utilizes the lookup table appears in one of the branch predictions. In the illustrated embodiment, the branch prediction unit is monitored (208) to determine whether an operation that utilizes the lookup table appears as the next instruction or the predicted next instruction. In other embodiments, other techniques for predicting that the look up table is required can be used such as an instruction requiring the look up table entering the processor pipeline. Once an operation that utilizes the lookup table appears, the integrated NVM module containing the lookup table is powered up (210) and the lookup table is loaded (212) from the non-volatile devices within the integrated NVM module into the volatile memory cells within the integrated NVM module.

In addition to a lookup tables, integrated NVM modules can be used to contain other types of information that is useful to circuits within the processing circuitry. In many embodiments, integrated NVM modules are used to store frames of video information in video encoding applications. In many encoders, information concerning the differences between adjacent frames in a sequence of frames can be used to greatly compress the amount of information required to represent the sequence of video frames. An embodiment of a process in accordance with the present invention for storing video frames in an integrated NVM module is shown in FIG. 10a. The process 220 includes determining (222) whether the time until the next sample or video frame is received is a time t that is greater than tc. In the event that a sample or video frame is unlikely to be received for a period of time greater than tc, then the frame of video information stored in the volatile memory cells within the integrated NVM module can be loaded into the non-volatile memory devices within the integrated NVM module and the integrated NVM module can be powered down (224). Once the integrated NVM module is powered down, then a determination (226) is made as to whether it is time to acquire the next video frame. In the event that the time to acquire the next sample or video frame has occurred, then the integrated NVM module containing the lookup table is powered up (228) and the frame of video information stored in the non-volatile memory devices is loaded (230) into the volatile memory cells within the integrated NVM module. The video frame can then be used to encode the next sample or video frame.

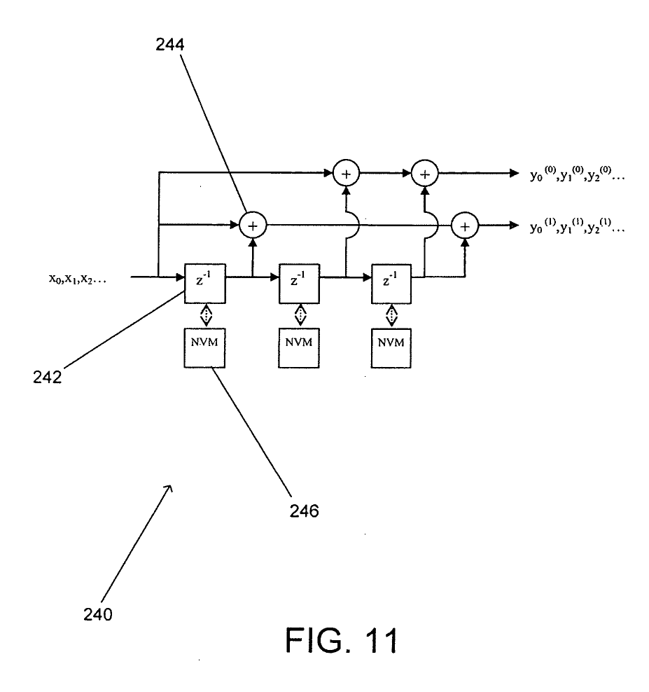

An embodiment of an integrated convolutional encoder circuit in accordance with the present invention that includes a plurality of integrated NVM modules is shown in FIG. 11. The convolutional encoder 240 includes a convolutional encoder circuit constructed from delay circuits 242 and summing circuits 244. In the illustrated embodiment, the configuration of the delay and summing circuits results in the following the outputs, where x₀, x₁ and x₂ are inputs to the circuit:
i y=x₀+x₂+x₃
y=x₀+x₁+x₃

In the illustrated embodiment, the delay circuits 242 are connected to integrated NVM modules 246. Values indicative of the state of the convolutional encoder can be stored in volatile memory cells for use by the encoder circuit and be loaded into non-volatile memory devices in the event that the convolutional encoder circuit is powered down.

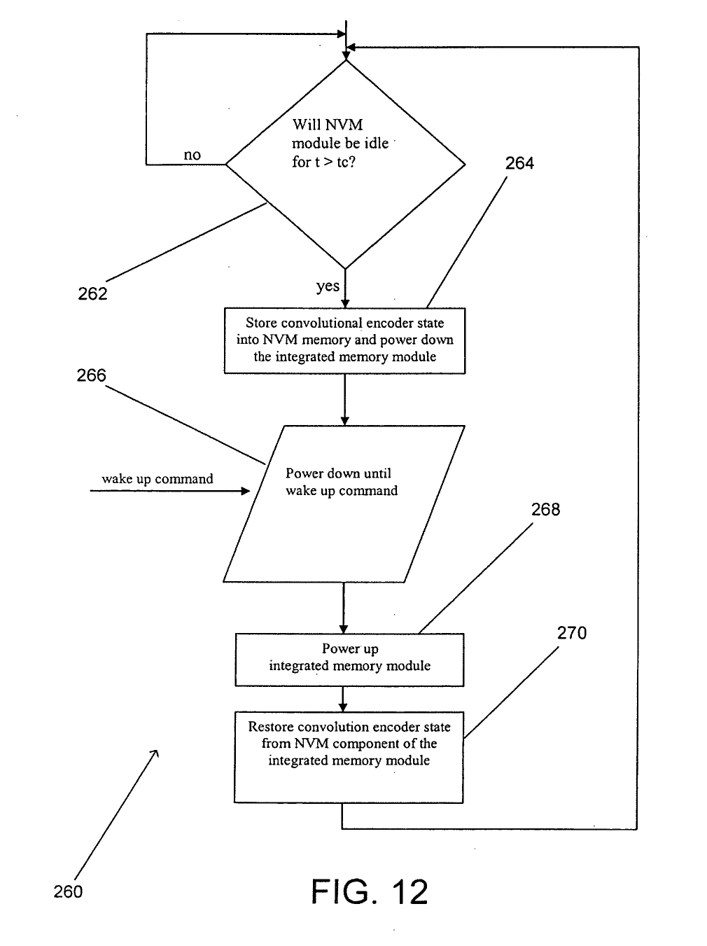

A process in accordance with the present invention for transferring information between volatile memory cells and non-volatile memory devices in integrated NVM modules that are part of an integrated convolutional encoder is shown in FIG. 12. The process 260 includes determining (262) whether the convolutional encoder circuit is likely to remain idle for a period of time t greater than tc. Embodiments of processes in accordance with the present invention for determining whether the convolutional encoder circuit is likely to remain idle for a period greater than tc are discussed above. In the event that a determination is made that the convolutional encoder circuit is likely to remain idle for a period of time t greater than tc, then the state of the convolutional encoder (i.e. the information stored in the volatile memory cells of the integrated NVM modules) can be loaded (264) into the non-volatile devices of the integrated NVM modules and the convolutional encoder circuit can be powered down. The process then waits (266) for a wake up command. In many embodiments, the wake up command can be provided by a power management system. Once a wake up command is received, power is supplied (268) to the convolutional encoder circuit and the convolutional encoder state is restored by loading (270) the information stored in the non-volatile devices in the integrated NVM modules into the volatile memory cells in the integrated NVM modules.

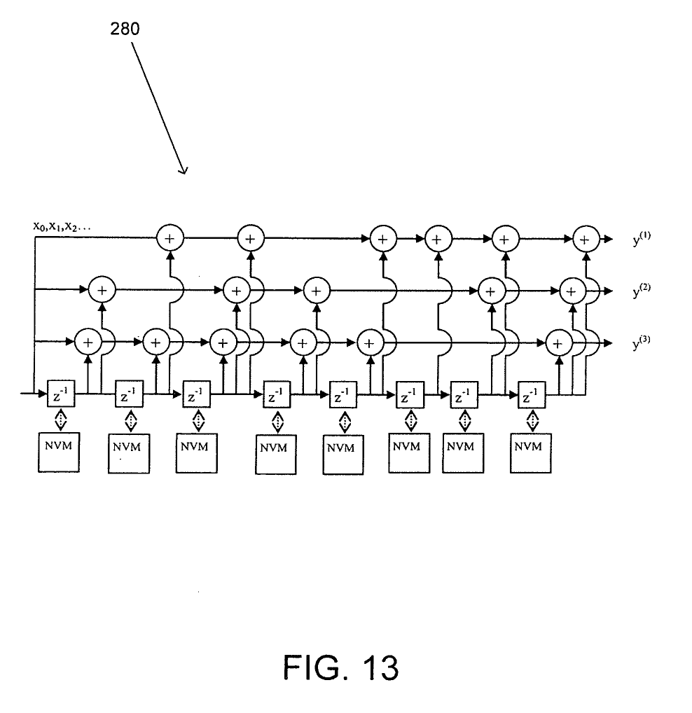

Another embodiment of a convolutional encoder in accordance with an embodiment of the present invention in which the state of the convolutional encoder can be loaded into integrated NVM modules is shown in FIG. 13. In the illustrated embodiment, the convolutional encoder 280 is configured to provide the following outputs y⁽¹⁾, y^{( 2)} and y⁽³⁾ are generated in response to a sequence of inputs xₙ are as follows:
y⁽¹⁾=x₀+x₁+x₂+x₃+x₅+x₆+x₈
y⁽²⁾=x₀+x₁+x₄+x₅+x₇+x₈
y⁽³⁾=x₀+x₃+x₄+x₅+x₆+x₇+x₈

Although specific convolutional encoders are described above, embodiments of the present invention can combine any convolutional encoder circuit with integrated NVM modules to provide the ability to store the state of the convolutional encoder circuit, when power supply is removed from the convolutional encoder circuits.

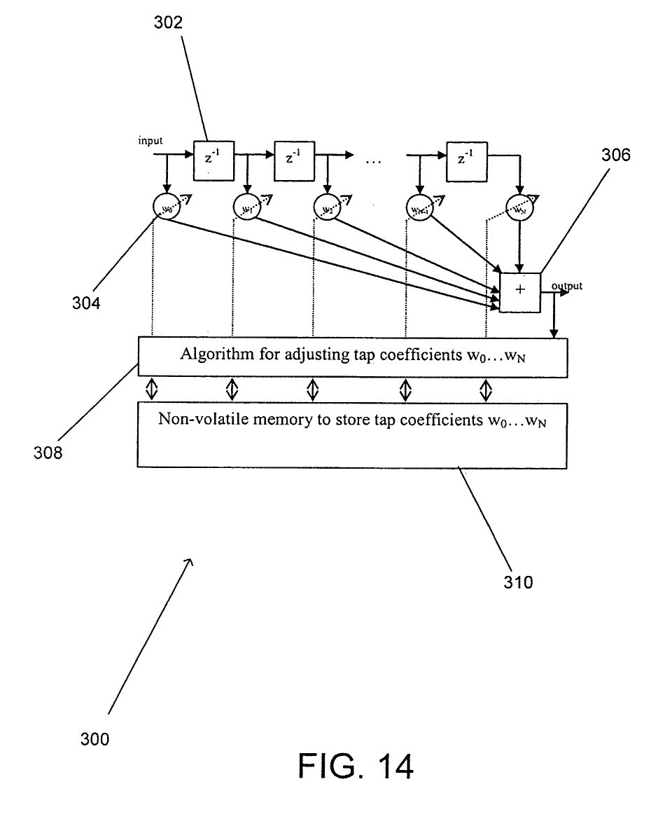

As discussed above, any type of integrated circuit that uses information that it is desirable to preserve in the event of a planned or unplanned interruption in power supply can be implemented using integrated NVM modules in accordance with the present invention. An embodiment of an adaptive equalizer in accordance with the present invention is shown in FIG. 14. The adaptive equalizer 300 includes a number of delay circuits 302, a number of tap circuits 304 and a summing circuit 306 that are configured to form a tapped delay line. The adaptive equalizer also includes circuitry 308 that sets the values of each of the tap coefficients of the tap circuits 304. Many examples of such circuitry are provided in the prior art. Integrated with the adaptive equalizer circuit is the circuitry of an integrated NVM module 310 that is connected to the circuitry 308 that sets the tap coefficients. The integrated NVM module 310 can be used to store the tap coefficients of the tapped delay line. When power is supplied to the adaptive equalizer, the tap coefficients can be stored in the volatile memory cells of the integrated NVM module 310. In the event that power supply is to be interrupted, the information stored in the volatile memory cells of the integrated NVM module 310 can be loaded into the non-volatile memory devices within the integrated NVM module.

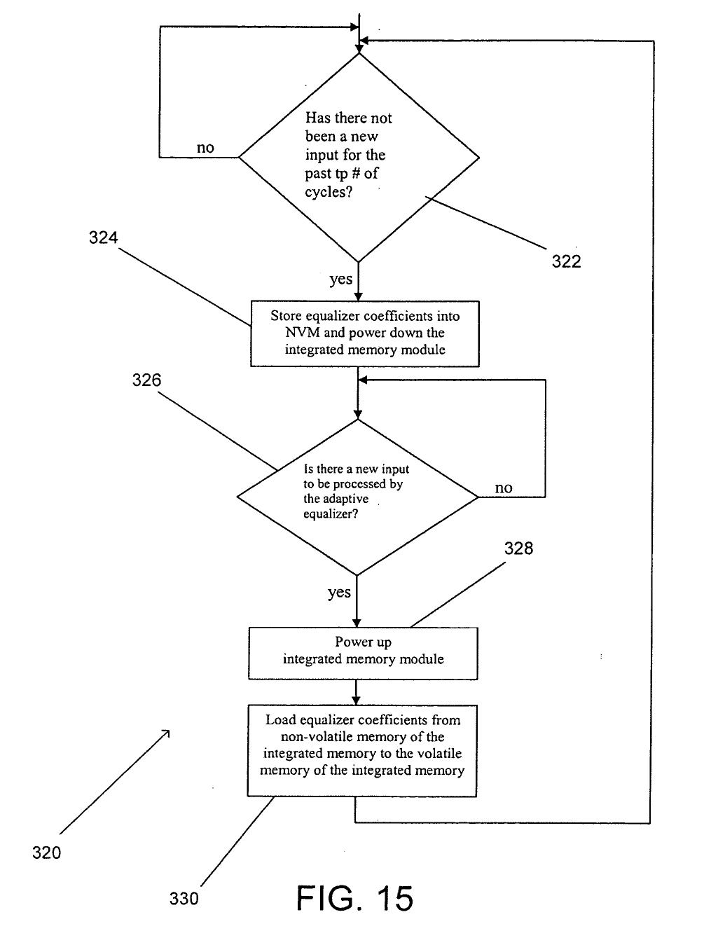

A process in accordance with the present invention for loading data between volatile memory cells and non-volatile memory devices of an integrated adaptive equalizer circuit that includes an integrated NVM module is shown in FIG. 15. The process 320 is similar to embodiments of processes described above for loading information between the volatile memory cells and the non-volatile memory devices of an integrated NVM module that is integrated with processing circuitry. The process 320 includes determining (322) whether the adaptive filter circuit is likely to remain idle for a period of time t greater than tc. Embodiments of processes in accordance with the present invention that can be used for determining whether the adaptive fileter circuit is likely to remain idle for a period greater than tc are discussed above. In the event that a determination is made that the adaptive filter circuit is likely to remain idle for a period of time t greater than tc, then the tap coefficients of the adaptive filter (i.e. information stored in the volatile memory cells of an integrated NVM module) can be loaded (264) into the non-volatile devices of the integrated NVM module and the adaptive filter can be powered down. The process then waits (266) for a wake up command. In many embodiments, the wake up command can be provided by a power management system. Once a wake up command is received, power is supplied (268) to the adaptive filter and the adaptive filter tap coefficients are restored by loading (270) the information stored in the non-volatile devices of the integrated NVM module into the volatile memory cells in the integrated NVM modules.

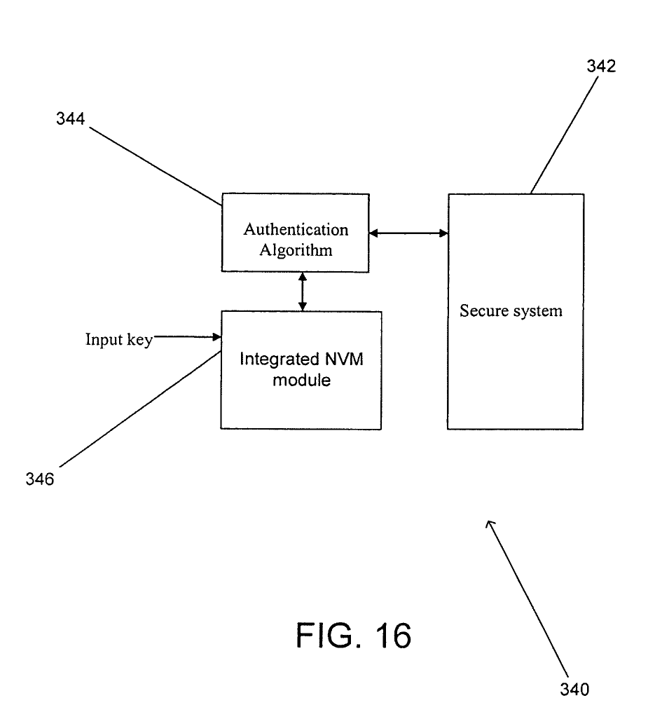

An embodiment of an encryption system in accordance with the present invention in which the encryption key can be stored in an integrated NVM module is shown in FIG. 16. The encryption system 340 includes a system 342 that is secured by an authentication system. The authentication system includes circuitry 344 for performing an authentication algorithm that is connected to an integrated NVM module 346 that can be used to store an authentication or encryption key.

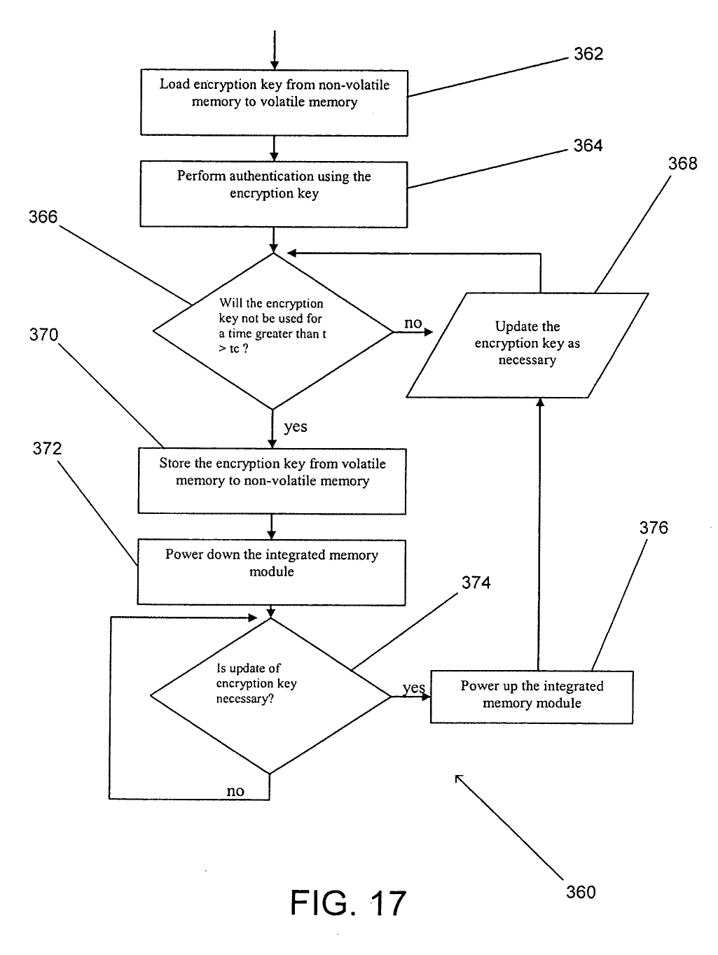

A process in accordance with the present invention for performing authentication in a secure system where an authentication key is stored in an integrated NVM module is shown in FIG. 17. The process 360 includes loading (362) the encryption key from non-volatile devices in the integrated NVM module into volatile memory cells. Authentication can then be performed (364) using the encryption key. A decision (366) is then made concerning whether the encryption key is likely to be required during a time period t that is greater than tc. In the event that the encryption key is likely to be required, then the encryption key is updated (368) as necessary and retained in the volatile memory cells of the integrated NVM module. When a determination is made that the encryption key is not likely to be required for a period of time greater than tc, then the encryption key can be loaded (370) into the non-volatile memory devices in the integrated NVM module and the integrated NVM module can be powered down (372). In the event that the encryption key is required, the circuitry can be powered up and the encryption key reloaded into the volatile memory cells of the integrated NVM module. In addition, the a determination (374) can be made that the encryption key requires updating. If the encryption key requires updating, then the integrated NVM memory module can be powered up (376) and the encryption key updated.

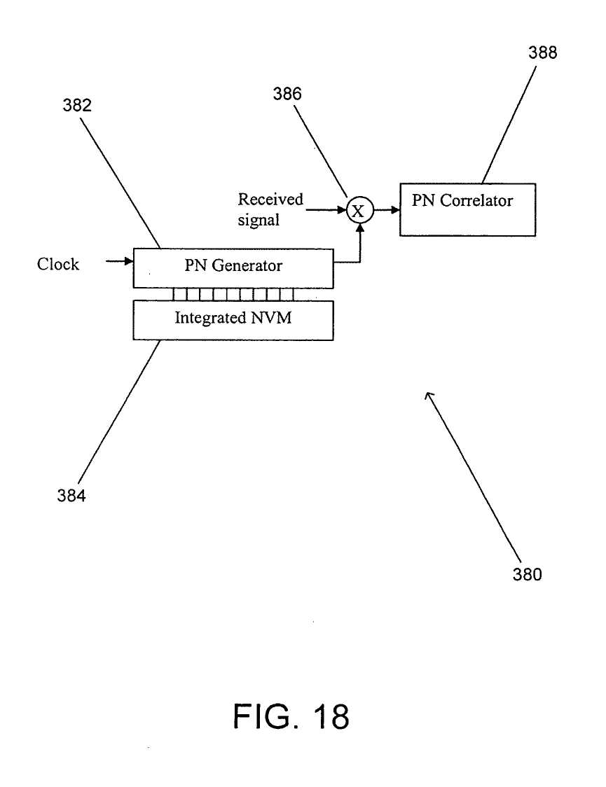

An embodiment of a Pseudorandom Noise (PN) generation circuit in accordance with an embodiment of the present invention that includes an integrated NVM module for storing the PN authentication state and key is illustrated in FIG. 18. As with many of the embodiments described above, the PN generation circuit can be integrated with the circuit of the integrated NVM module on a single chip or device. The PN generation circuit 380 includes a PN Generator 382 that is connected to a clock signal and an integrated NVM module 384. An output of the PN Generator is provided to a multiplier 386 that combines the PN signal generated by the PN Generator 384 with a received input signal. An output from the multiplier 386 is provided to a PN Correlator 388. As with many of the embodiments described above, the PN authentication state and key can be loaded into non-volatile devices within the integrated NVM module when a determination is made that the PN Generation circuit is likely to remain idle and the integrated NVM module can be powered down.

Several of the embodiments described above have combined processing circuitry with one or more integrated NVM modules. The integration of separate integrated NVM modules and associated circuits in a single chip is also discussed. In many embodiments, processing circuitry performing different functions can be integrated into a number of separate chips that each include an integrated NVM modules.

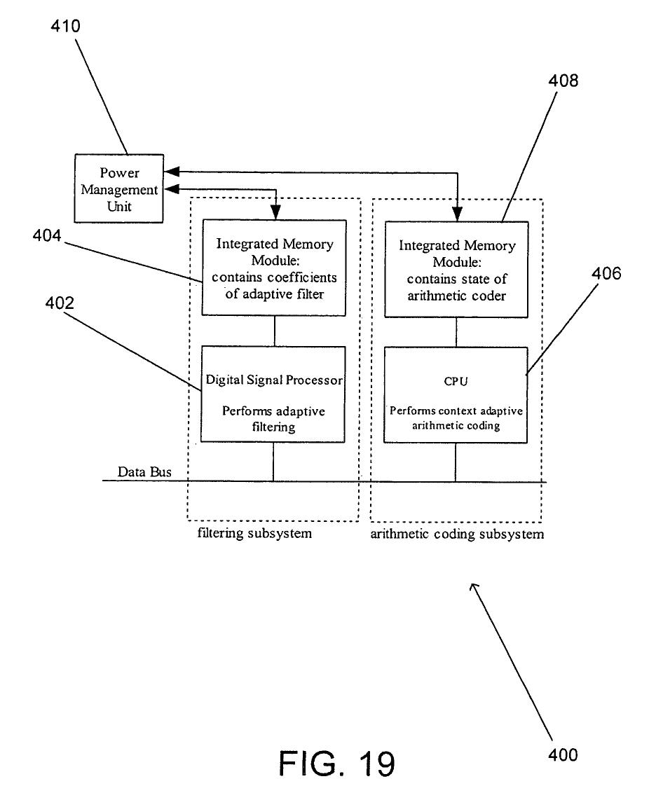

An embodiment of an adaptive filtering arithmetic coding system is shown in FIG. 19. The adaptive filtering arithmetic coding system 400 includes a digital signal processing circuit 402 that is connected to an integrated NVM module 404. The adaptive filtering arithmetic coding system also includes a CPU 406 that is connected to a second integrated NVM module 408. The digital signal processing circuit 402 and the CPU 406 are connected via a bus system and both the first and second integrated NVM modules are connected to a power management unit 410. The digital signal processing circuitry 402 can be used to perform digital filtering of information and is configured to store information in the first integrated NVM module 404. The CPU 406 can be used to perform context adaptive arithmetic coding and is configured to store information in the second integrated NVM module 408. In a fashion similar to embodiments described above, the illustrated adaptive filtering arithmetic coding system can power down the integrated NVM modules to preserve information while conserving power.

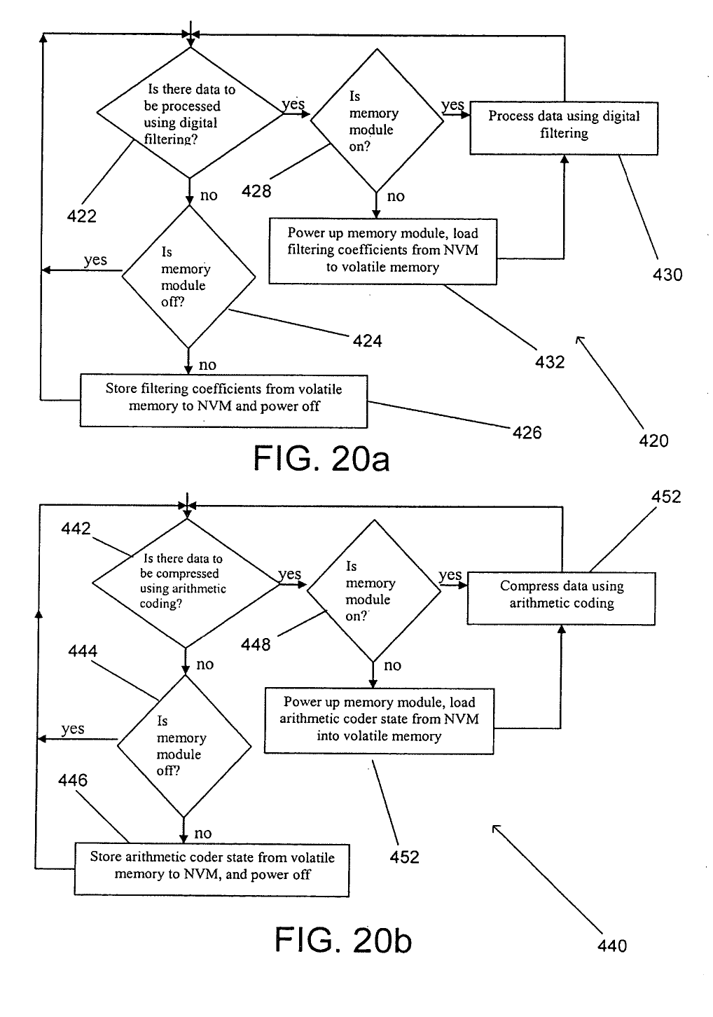

An embodiment of a process that can be used by an adaptive filtering arithmetic coding system in accordance with the present invention to preserve information and conserve power is shown in FIG. 20a. The process 420 includes determining (422) whether any information requires filtering by the digital processor circuitry. If a determination is made that no information is available that requires filtering, then information associated with the digital signal processing circuitry such as the coefficients of a digital filter can be loaded (424) from volatile memory cells in the first integrated NVM module into non-volatile memory devices in the first integrated NVM module. Once the information has been loaded, the integrated NVM module can be powered down (426) until more information is available for filtering.

In the event that information is available for filtering, then a determination (428) is made concerning whether the first integrated NVM module is powered. If the integrated NVM module is powered, the information can be processed (430). If the integrated NVM module is powered down, then power can be restored (432) to the NVM module and information relevant to the digital signal processing circuitry can be loaded from non-volatile memory devices within the integrated NVM module to volatile memory cells within the integrated NVM module. Once the information has been loaded into the volatile memory cells, then filtering can be performed (430).

A similar process to that described above is shown in FIG. 20bfor coordinating the transfer of data between volatile memory cells and non-volatile memory devices of an integrated NVM module connected to a CPU in an adaptive filtering arithmetic coding system. The process 440 is similar to the process 40 shown in FIG. 20a with the exception that the initial determination (442) involves ascertaining whether any data requiring compression is present and the fact that the information stored in the integrated NVM module includes information concerning the state of the arithmetic encoder.

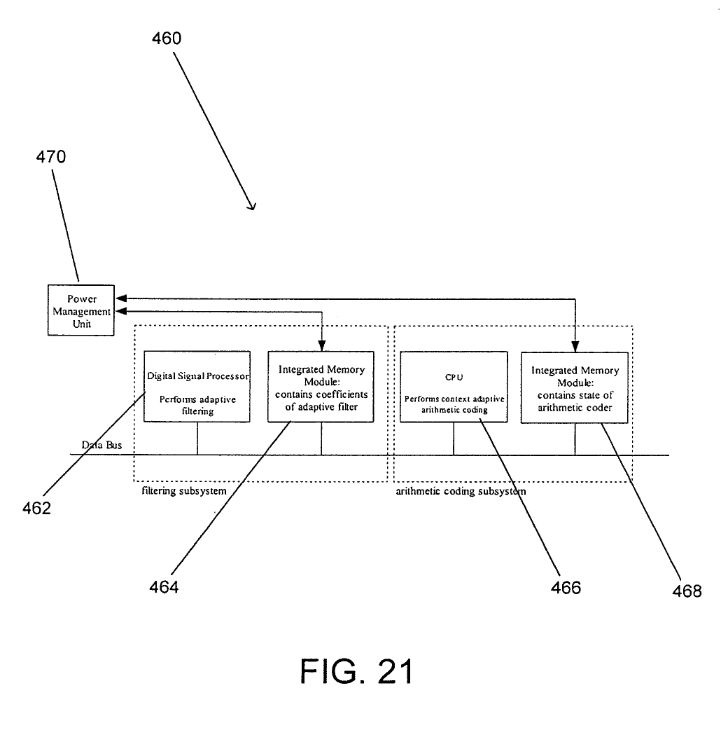

Another embodiment of an adaptive filtering arithmetic coding system in accordance with the present invention is shown in FIG. 21. The adaptive filtering arithmetic coding system 460 shown in FIG. 21 is similar to the adaptive filtering arithmetic coding system 400 shown in FIG. 19 with the exception that digital signal processing circuitry 462, the first integrated NVM module 464, the CPU 466 and the second integrated NVM module 468 are all connected via a bus system. Although the power management unit 470 is shown as being connected to the first and second integrated NVM modules in FIG. 21, many embodiments include a power management unit that is connected to one or both of the digital signal processing circuitry 462 and the CPU 466. In many embodiments, the digital signal processing circuitry 462 and the CPU 466 can also be partially and/or entirely powered down by the power management unit 470 in order to conserve power.

Variations, modifications, and other implementations of what is described herein will occur to those of ordinary skill in the art without departing from the spirit and the scope of the invention as claimed. For example, processing circuitry, circuits of an integrated NVM module and/or power management circuit can be integrated on a single circuit or device. In addition, a single chip can include multiple integrated NVM modules. Furthermore, information can be loaded between one of many volatile memory cells and a non-volatile memory device and/or between one volatile memory cell and many non-volatile memory devices. Although the invention has been described with respect to certain embodiments, it should be recognized that the invention includes the claims and their equivalents supported by this disclosure.

What is claimed is:

1. An architecture, comprising:
processing circuitry connected to an integrated non-volatile memory module; and
a power supply connected to the processing circuitry and integrated non-volatile memory module;
wherein the integrated non-volatile memory module is integrated on a single chip and includes at least one volatile memory cell that is connected to at least one non-volatile memory device.

2. The architecture of claim 1, wherein the integrated non-volatile memory module includes at least one control input that is configured to load data stored in a volatile memory cell into a non-volatile memory device.

3. The architecture of claim 2, wherein:
the processor is configured to provide a signal to the at least one control input of the integrated non-volatile memory module that causes data to be loaded from a volatile memory cell in the integrated non-volatile memory into a non-volatile memory device in the integrated non-volatile memory; and
the processor is configured to provide a signal to the power supply that causes the power supply to remove power to the volatile memory cell and the non-volatile memory device in the integrated non-volatile memory module.

4. The architecture of claim 2, wherein:
the power supply is configured to provide a signal to the at least one control input of the integrated non-volatile memory module that causes data to be loaded from a volatile memory cell in the integrated non-volatile memory module into a non-volatile memory device in the integrated non-volatile memory module; and
the power supply is configured to remove power to the volatile memory cell and the non-volatile memory device in the integrated non-volatile memory module.

5. The architecture of claim 4, wherein:
the power supply receives power from an external power source; and
the power supply is configured to sense an actual or impending interruption to the supply of power from the external power source.

6. The architecture of claim 5, wherein the power supply includes a battery as a power source in addition to the external power source.

7. The architecture of claim 1, wherein the integrated non-volatile memory module includes at least one control input that is configured to load data stored in a non-volatile memory device into a volatile memory cell.

8. The architecture of claim 7, wherein:
the processor is configured to provide a signal to the power supply that causes the power supply to provide power to a volatile memory cell and a non-volatile memory device in the integrated non-volatile memory module; and
the processor is configured to provide a signal to the at least one control input of the integrated non-volatile memory module that causes data to be loaded from the non-volatile memory device into the volatile memory cell.

9. The architecture of claim 2, wherein:
the power supply is configured to controllably supply power to a volatile memory cell and a non-volatile memory device in the integrated non-volatile memory module; and
the power supply is configured to provide a signal to the at least one control input of the integrated non-volatile memory module that causes data to be loaded from the non-volatile memory device into the volatile memory cell.

10. The architecture of claim 1, wherein the processing circuitry and integrated non-volatile memory module are connected via a bus system.

11. The architecture of claim 2, further comprising a hard disk drive connected to the processing circuitry and the integrated non-volatile memory module via the bus system.

12. The architecture of claim 11, wherein the processing circuitry includes a central processing unit.

13. The architecture of claim 10, further comprising non-volatile memory connected to the processing circuitry and the integrated NVM module via the bus system.

14. The architecture of claim 13, wherein the processing circuitry includes a video game processor.

15. The architecture of claim 10, wherein the processing circuitry includes an embedded processor.

16. The architecture of claim 1, wherein the processing circuitry and the integrated non-volatile memory module are integrated on the same chip.

17. The architecture of claim 1, wherein:
the processing circuitry includes an adaptive equalizer connected to the integrated non-volatile memory module; and
wherein the tap coefficients of the adaptive equalizer are stored in the integrated non-volatile memory module.

18. The architecture of claim 1, wherein:
the processing circuitry includes an authentication circuit connected to the integrated non-volatile memory module; and
an encryption key is stored in the integrated non-volatile memory module.

19. The architecture of claim 18, wherein:
the processing circuitry includes a psuedorandom noise generator connected to the integrated non-volatile memory module; and
wherein a psuedorandom noise authentication state and key are stored in the integrated non-volatile memory module.

20. The architecture of claim 1, wherein:
the processing circuitry includes multiple processing circuits; and
the single integrated device includes multiple integrated non-volatile memory modules that are connected to different processing circuits.

21. The architecture of claim 20, wherein:
the processing circuitry includes a convolutional encoder connected to a plurality of integrated non-volatile memory modules; and
the state of the convolution encoder is stored in the integrated non-volatile memory modules.

22. The architecture of claim 20, wherein the processing circuitry includes multiple processing circuits distributed across multiple integrated devices and a plurality of those integrated devices also include at least one integrated non-volatile memory module.

23. The architecture of claim 22, wherein:
one of the devices includes a digital signal processor and an integrated non-volatile memory module;
a second device includes a central processor unit and an integrated memory module; and
both of the devices are connected to the power supply.

24. The architecture of claim 1, further comprising:
a second integrated non-volatile memory module connected to the power supply;
wherein the processing circuitry includes:
a digital signal processor integrated on a first device;
a central processing unit integrated on a second device;
wherein the digital signal processor, the central processing unit, the first integrated non-volatile memory module and the second integrated non-volatile memory module are connected via a bus system.

25. A process for transferring information from a volatile memory cell in an integrated non-volatile memory module to an integrated memory device in the integrated non-volatile memory module where the integrated non-volatile memory module is contained on a single chip, comprising:
determining whether a portion of the integrated non-volatile memory module that includes the volatile memory cell and the integrated non-volatile device is likely to be required within a predetermined time period;
loading information in the volatile memory cell into the non-volatile device; and
removing power from the volatile memory cell and the non-volatile device.

26. The process in claim 25, further comprising:
waiting for the portion of the integrated non-volatile memory to be required;
waking up the portion of the integrated non-volatile memory; and
loading data from the non-volatile memory device into the volatile memory cell.

27. The process in claim 25, wherein determining whether a portion of the integrated non-volatile memory that includes the volatile memory cell and the integrated non-volatile device is likely to be required further comprises receiving a user instruction indicative of the portion of integrated non-volatile memory not being required.

28. The process in claim 25, wherein determining whether a portion of the integrated non-volatile memory that includes the volatile memory cell and the integrated non-volatile device is likely to be required further comprises receiving an automatically generated instruction indicative of the portion of integrated non-volatile memory not being required.

29. The process in claim 28, wherein an instruction is automatically generated when the portion of the integrated non-volatile memory has not been required for a second predetermined period of time.

30. The process of claim 29, wherein the duration of the second predetermined period of time is determined by performing analysis of the frequency with which the portion of integrated non-volatile memory is required.

31. The process of claim 25, wherein the portion of integrated non-volatile memory is an entire integrated non-volatile memory module.
